(19) United States
(12) Patent Application Publication
(10) Pub. No.: US 2018/0259805 A1
(43) Pub. Date: Sep. 13, 2018

(54) DISPLAY DEVICE

(71) Applicant: Japan Display Inc., Tokyo (JP)

(72) Inventor: Toshifumi TAKEHARA, Tokyo (JP)

(21) Appl. No.: 15/911,594

(22) Filed: Mar. 5, 2018

(30) Foreign Application Priority Data
Mar. 10, 2017 (JP) 2017-045915

(51) Int. Cl. G02F 1/1333; G02F 1/1362; G02F 1/1339; G02F 1/1335; H01L 27/12

(52) U.S. Cl. CPC G02F 1/133305; G02F 1/136209; G02F 1/1339; G02F 2201/121; H01L 27/1225; G02F 2201/123; G02F 1/133528

(57) ABSTRACT

Provided is a display device which includes: a first glass substrate; a first base material over the first glass substrate, the first base material having a first flat region and a first bending region; an electro-optical element over the first flat region and the first bending region; and a second base material over the electro-optical element. The first base material is in contact with the first glass substrate in the first flat region and is spaced from the first glass substrate in the first bending region.

### CROSS REFERENCE TO RELATED APPLICATIONS

This application is based on and claims the benefit of priority from the prior Japanese Patent Application No. 2017-045915, filed on Mar. 10, 2017, the entire contents of which are incorporated herein by reference.

### FIELD

An embodiment of the present application relates to a display device and a manufacturing method thereof.

### BACKGROUND

A liquid crystal display device and an organic EL (Electroluminescence) display device have been known as a typical example of a display device. Among them, a liquid crystal display device has been most widely used as a flat panel display. A liquid crystal display device includes a liquid crystal element as an electro-optical element over a substrate, and the liquid crystal element possesses, as a fundamental structure, a pair of electrodes (a pixel electrode and an opposing electrode (alternatively, a common electrode)) and a layer (liquid crystal layer) of a compound (liquid crystal) having liquid crystallinity sandwiched by the pair of electrodes. The use of a plastic substrate or a glass substrate having flexibility as a substrate provides flexibility to a display device. For example, liquid crystal display devices each having a liquid crystal element over a flexible substrate are disclosed in Japanese Patent Application Publications No. 2012-208184 and 2013-122471 and Japanese Translation of PCT International Application Publication No. 2015-501461. Japanese Translation of PCT International Application Publications No. 2016-517359 and 2016-523796 disclose display devices utilizing a flexible glass substrate. Note that an electro-optical element is not limited to a liquid crystal element and may be an element, such as an organic light-emitting element, an inorganic light-emitting element, a MEMS (Micro Electro Mechanical System) shutter, and an electrophoretic element, whose optical properties are changed by using electricity.

### SUMMARY

An embodiment of the present invention is a display device. The display device includes: a first glass substrate; a first base material over the first glass substrate, the first base material having a first flat region and a first bending region; and an electro-optical element in the first flat region. The first base material is in contact with the first glass substrate in the first flat region and is spaced from the first glass substrate in the first bending region.

An embodiment of the present invention is a display device. The display device includes: a first glass substrate; a first base material over the first glass substrate, the first base material having a first flat region and a first bending region; an electro-optical element over the first flat region and the first bending region; a second base material over the electro-optical element, the second base material having a second flat region and a second bending region; and a second glass substrate over the second base material. The first base material is in contact with the first glass substrate in the first flat region and is spaced from the first glass substrate in the first bending region. The second base material is in contact with the second glass substrate in the second flat region.

### BRIEF DESCRIPTION OF DRAWINGS

FIG. 1 is a schematic perspective view of a display device according to an embodiment of the present invention;

FIG. 2 is a schematic perspective view of a display device according to an embodiment of the present invention;

FIG. 3 is a schematic top view of a display device according to an embodiment of the present invention;

FIG. 4A and FIG. 4B are schematic cross-sectional views of a display device according to an embodiment of the present invention;

FIG. 5 is a schematic top view of a pixel of a display device according to an embodiment of the present invention;

FIG. 6 is a schematic cross-sectional view of a pixel of a display device according to an embodiment of the present invention;

FIG. 7A to FIG. 7D are schematic cross-sectional views for explaining a manufacturing method of a display device according to an embodiment of the present invention;

FIG. 8A and FIG. 8B are schematic cross-sectional views for explaining a manufacturing method of a display device according to an embodiment of the present invention;

FIG. 9A to FIG. 9C are schematic cross-sectional views for explaining a manufacturing method of a display device according to an embodiment of the present invention;

FIG. 10A is a schematic cross-sectional view and FIG. 10B and FIG. 10C are schematic perspective views for explaining a manufacturing method of a display device according to an embodiment of the present invention;

FIG. 11A to FIG. 11E are schematic cross-sectional views for explaining a manufacturing method of a display device according to an embodiment of the present invention;

FIG. 12A and FIG. 12B are schematic cross-sectional views of a display device according to an embodiment of the present invention;

FIG. 13 is a schematic cross-sectional view of a display device according to an embodiment of the present invention;

FIG. 14A and FIG. 14B are schematic cross-sectional views of a display device according to an embodiment of the present invention;

FIG. 15A is a top view and FIG. 15B and FIG. 15C are schematic cross-sectional views for explaining a manufacturing method of a display device according to an embodiment of the present invention;

FIG. 16 is a schematic cross-sectional view of a display device according to an embodiment of the present invention;

FIG. 17A and FIG. 17B are schematic cross-sectional views for explaining a manufacturing method of a display device according to an embodiment of the present invention;

FIG. 18A and FIG. 18B are schematic cross-sectional views of a display device according to an embodiment of the present invention; and

FIG. 19 is a schematic cross-sectional view of a display device according to an embodiment of the present invention.

### DESCRIPTION OF EMBODIMENTS

An object of an embodiment of the present invention is to provide a display device having a bent display region at an edge portion and a manufacturing method thereof. Alternatively, an object of an embodiment of the present invention is to provide a display device in which a wide display area is secured and a method for manufacturing the display device at a high yield and low cost.

Hereinafter, the embodiments of the present invention are explained with reference to the drawings. The invention can be implemented in a variety of different modes within its concept and should not be interpreted only within the disclosure of the embodiments exemplified below.

The drawings may be illustrated so that the width, thickness, shape, and the like are illustrated more schematically compared with those of the actual modes in order to provide a clearer explanation. However, they are only an example, and do not limit the interpretation of the invention. In the specification and the drawings, the same reference number is provided to an element that is the same as that which appears in preceding drawings, and a detailed explanation may be omitted as appropriate.

In the present invention, when a plurality of films is formed by processing one film, the plurality of films may have functions or rules different from each other. However, the plurality of films originates from a film formed as the same layer in the same process and has the same layer structure and the same material. Therefore, the plurality of films is defined as films existing in the same layer.

In the specification and the scope of the claims, unless specifically stated, when a state is expressed where a structure is arranged “over” another structure, such an expression includes both a case where the substrate is arranged immediately above the “other structure” so as to be in contact with the “other structure” and a case where the structure is arranged over the “other structure” with an additional structure therebetween. In the specification, unless specifically stated, an expression such as “a includes A, B, or C”, “a includes one of A, B, and C”, and “a includes one selected from a group consisting of A, B, and C” does not exclude a case where a includes a plurality of combinations of A to C. Additionally, these expressions do not exclude a case where a includes another element.

In the present specification and claims, an expression “a structure is exposed from another structure” means a state where a part of the structure is not covered by the other structure and includes a state where the portion of the structure which is not covered by the other structure is further covered by yet another structure.

### First Embodiment

In the present embodiment, a display device according to an embodiment of the present invention is explained. In the present embodiment, a structure of a display device 100 having a liquid crystal element is explained as an example of a display device.

### 1. Outline Structure

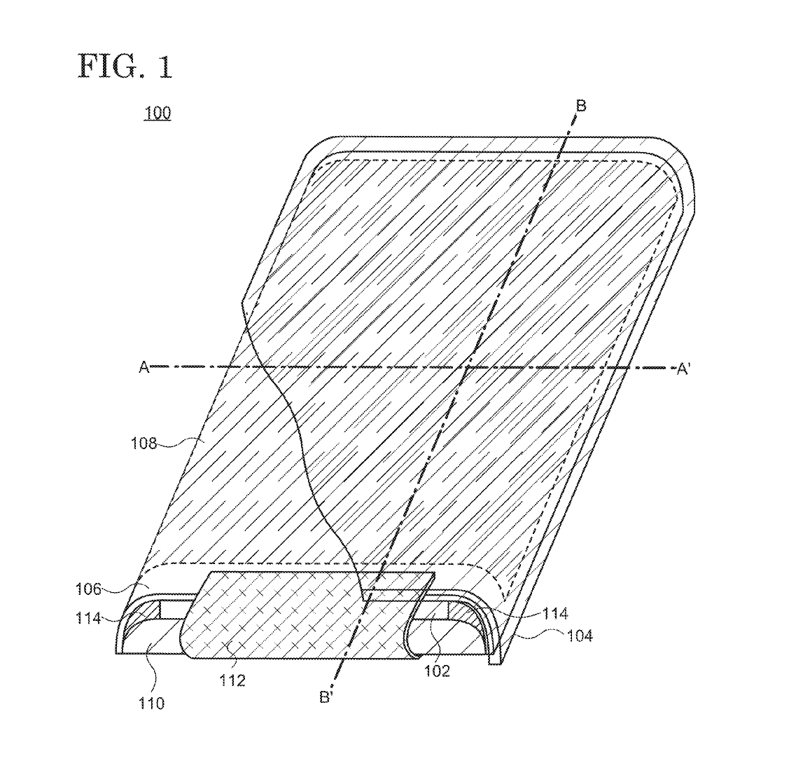

FIG. 1 is a schematic perspective view of the display device 100. As shown in FIG. 1, the display device 100 has a glass substrate (first substrate) 102 and a display unit 106 over the glass substrate 102. As described below in detail, an active region 108 is fabricated in the display unit 106. A backlight 110 is disposed under the display unit 106.

The glass substrate 102 has a flat or a substantially flat shape. On the other hand, the display unit 106 is processed to have bent edge portions. In the display device 100 shown in FIG. 1, both edge portions on the long sides of the display unit 106 are bent so as to cover side surfaces of the glass substrate 102 and edge portions of the backlight 110. Therefore, a part of the display unit 106 possesses a flat shape overlapping with the glass substrate 102 and a part of the display device 106 has a bent shape which does not overlap with the glass substrate 102.

Similar to the display unit 106, both edge portions of a top surface of the backlight 110 may be bent. In the example shown in FIG. 1, the backlight 110 is configured so that both edge portions are bent along the long sides of the display device 100 and a thickness thereof decreases approaching the edge portions. A space surrounded by the glass substrate 102, the display unit 106, and the backlight 110 is filled with a filler 114. A top surface and a bottom surface of the filler 114 are also bent due to the bending of the display unit 106 and a top surface of the backlight 110.

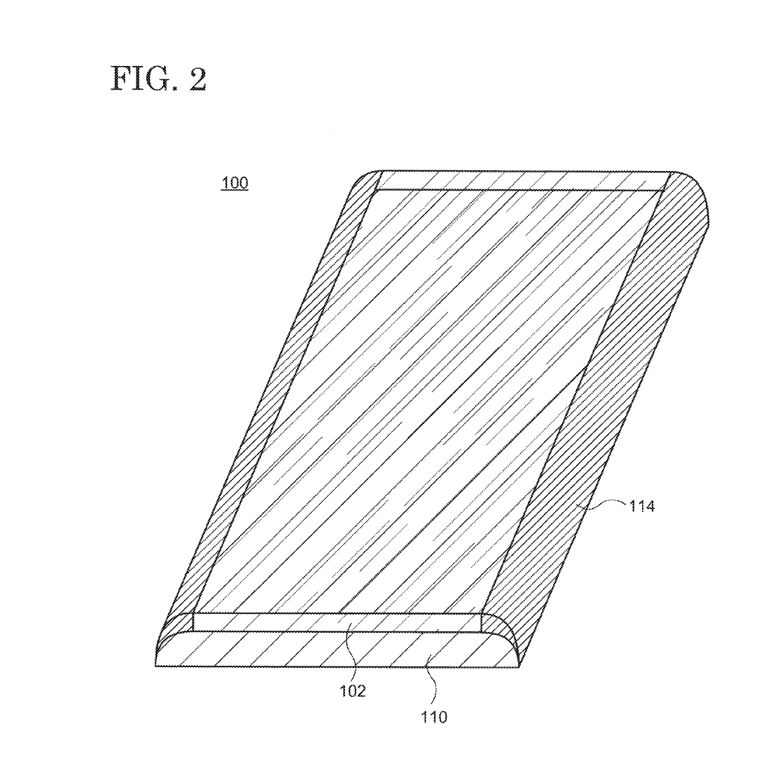

A connector 112 such as a flexible printed circuit (FPC) substrate is connected to the display unit 106. A variety of signals such as image signals are supplied from an external circuit such as a printed circuit substrate and input to the active region 108 through the connector 112. The display device 100 further possesses a cover member 104 covering the display unit 106. Similar to the display unit 106, the cover member 104 also may have a shape in which both edge portions thereof are bent, and the edge portions overlap with the bent edge portions of the display unit 106 and the backlight 110. A perspective view of the display device 100 in a state where the cover member 104, the display unit 106, and the connector 112 are removed is shown in FIG. 2. The filler 114 is arranged along both edge portions on the long sides of the glass substrate 102. The filler 114 is provided so that top surfaces of the glass substrate 102 and the filler 114 are continuously arranged. In this case, an angle between a normal line of the top surface of the filler 114 and the top surface of the glass substrate 102 continuously changes from a boundary between the filler 114 and the glass substrate 102 to an edge portion of the filler 114. In a similar way, bottom surfaces of the glass substrate 102 and the filler 114 are arranged continuously along the top surface of the backlight 110. The aforementioned shapes of the display unit 106, the backlight 110, and the cover member 104 allow the display device 100 to have a flat portion and bending portions sandwiching the flat portion.

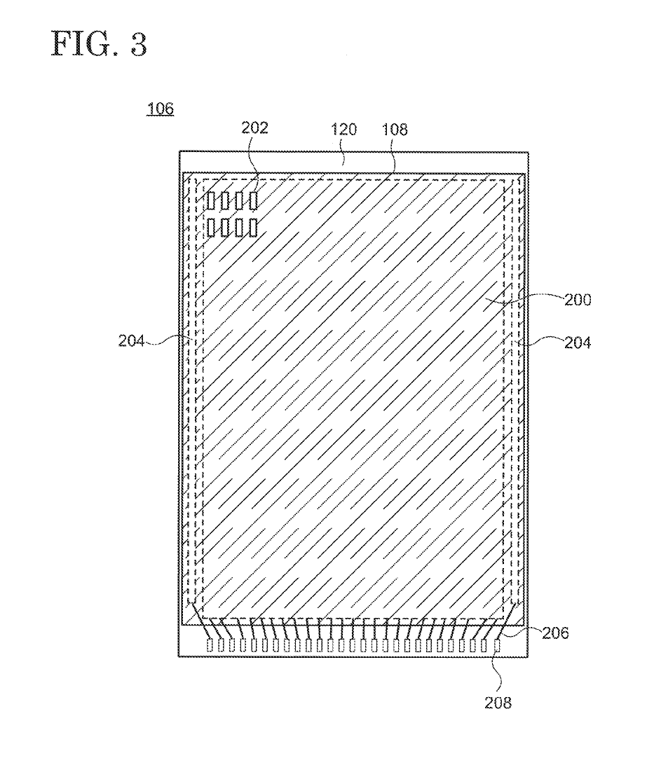

A schematic top view of the display unit 106 is shown in FIG. 3. In this figure, a state is illustrated where the whole of the display unit 106 has a plane shape in order to promote understanding.

As described below, the display unit 106 is structured with a first base material 120 and a second base material 122 (not shown in FIG. 3) as well as a liquid crystal layer 124 and a variety of insulating films, conductive films, and semiconductor films placed between the first base material 120 and the second base material 122, and the structural elements such as the active region 108, wirings 206, and terminals 208 are constituted by these layers and films. Therefore, in the present specification and claims, the display unit 106 includes the first base material 120, the second base material 122, and the liquid crystal layer 124 sandwiched therebetween.

The active region 108 possesses a plurality of pixels 202 and driver circuits 204. The pixels 202 may be arranged in a matrix form, and a display region 200 is defined by these pixels 202. An arrangement pattern of the pixels 202 can be arbitrarily selected, and the pixels 202 may be arranged so that a part of the pixels 202 is located in the bending portion of the display device 100. The pixels 202 each may be provided with a liquid crystal element, a transistor for driving the liquid crystal element, and the like. The transistor in each pixel 202 is controlled by the driver circuits 204. An example is shown in FIG. 3 where two driver circuits 204 are disposed so as to sandwich the display region 200. However, a single driver circuit 204 may be provided over the first base material 120.

The wirings 206 extend from the display region 200 and the driver circuits 204 to an edge portion of the first base material 120, and edge portions of the wirings 206 form terminals 208. The variety of signals supplied via the connector 112 are input to the terminals 208 and provided to the driver circuits 204 and the display region 200 to control the pixels 202, by which an image is displayed on the display region 200. Although not shown, a driver circuit may be additionally provided between the display region 200 and the terminals 208. This driver circuit may be formed over the first base material 120. Alternatively, an IC chip or the like formed over another substrate may be disposed over the first base material 120 and used as a driver circuit. Alternatively, an IC chip may be arranged as a driver circuit over the connector 112.

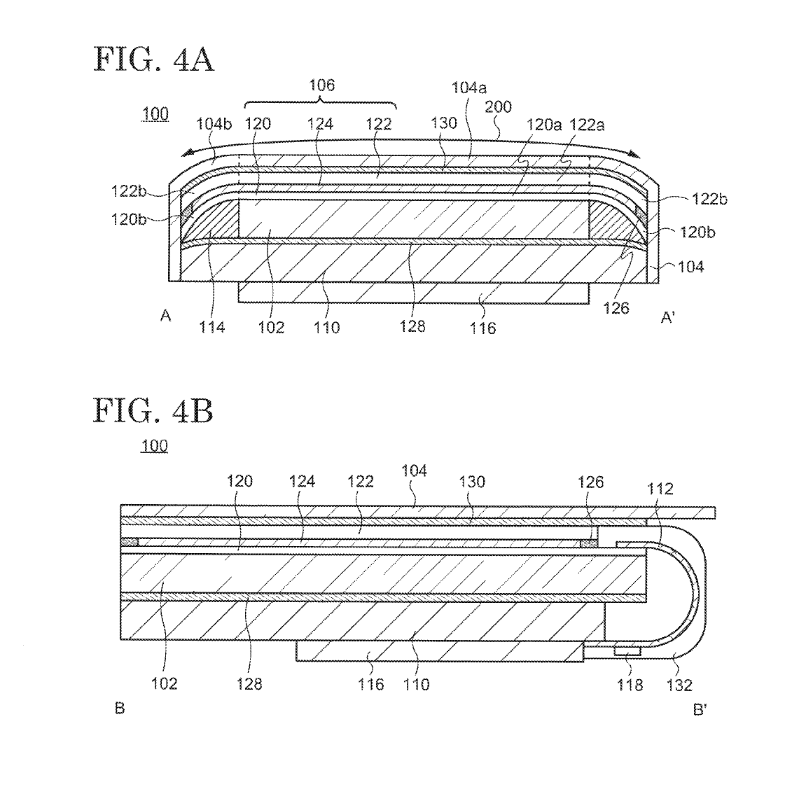

Schematic cross-sectional views along chain lines A-A′ and B-B′ of FIG. 1 are shown in FIG. 4A and FIG. 4B, respectively. Here, the variety of films provided between the first base material 120 and the second base material 122 are not illustrated.

As shown in FIG. 4A, the first base material 120 has a flat region 120a in which a top surface of the first base material 120 is flat and bending regions 120b. The bending regions 120b are formed along long sides of the first base material 120 and are bent in a direction toward the backlight 110 located under the glass substrate 102. The first base material 120 is in contact with the glass substrate 102 in the flat region 120a. On the other hand, a boundary between the flat region 120a and the bending region 120b overlaps with a ridge between the top surface and the side surface of the glass substrate 102, while the first base material 120 is spaced from the glass substrate 102 in the bending regions 120b. Hence, the top surface of the glass substrate 102 and a bottom surface of the first base material 120 are spaced from each other in the bending regions 120b. As shown in FIG. 4A, the bending regions 120b may be disposed at both edge portions of the first base material 120. In this case, the flat region 120a is sandwiched by the two bending regions 120b.

The filler 114 may be formed so as to be in contact with the side surface of the glass substrate 102, and the bottom surface of the first base material 120 may be in contact with the filler 114 in the bending regions 120b.

The first base material 120 and the second base material 122 are bonded with a seal 126, and a gap therebetween is filled with a liquid crystal to form the liquid crystal layer 124. The liquid crystal layer 124 overlaps with the glass substrate 102 and the filler 114.

Similar to the first base material 120, the second base material 122 also possesses a flat region 122a and bending regions 122b. The bending regions 122b are formed along long sides of the second base material 122 and are bent in a direction toward the backlight 110. The flat region 122a is formed so as to overlap with the glass substrate 102 and the flat region 120a of the first base material 120. On the other hand, the second base material 122 overlaps with the filler 114 and the bending regions 120b of the first base material 120 in the bending regions 122b. The bending regions 122b may be formed at both edge portions of the second base material 122. In this case, the flat region 122a is sandwiched by the two bending regions 122b.

As shown in FIG. 4A, the cover member 104 may be also configured so as to have a flat region 104a and bending regions 104b. The flat region 104a may overlap with the glass substrate 102 and the flat regions 120a and 122a. On the other hand, the bending regions 104b may overlap with the filler 114 and the bending regions 120b and 122b. The cover member 104 may be further configured so as to have a side surface extending in a downward direction from the bending regions 104b. In this case, the cover member 104 may be disposed so as to be in contact with side surfaces of the second base material 122, the first base material 120, and the backlight 110, allowing the display unit 106, the filler 114 and the backlight 110 to be covered by the cover member 104.

Although not shown in the figure, each of the first base material 120, the second base material 122, and the cover member 104 may respectively have a single bending region 120b, 122b, or 104b and a single flat region 120a, 122a, or 104a. In this case, the display device 100 performs display on the side surface at one edge portion, while display is not performed on the side surface at the other edge portion. In addition, it is not necessary that the bending regions 120b and 122b be used as a display region. Similarly, it is not necessary that the bending regions 120b and 122b overlap with any electro-optical element. Bending the edge portions allows a frame of the display device 100 to be narrowed.

The display device 100 may further possess a polarizing plate (first polarizing plate) 128 and a polarizing plate (second polarizing plate) 130 between the backlight 110 and the glass substrate 102 and between the second base material 122 and the cover member 104, respectively. A polarization plane of polarized light incident on the liquid crystal layer 124 from the backlight 110 through the first polarizing plate 128 is rotated by the liquid crystal layer 124 and is output through the second polarizing plate 130. The rotation of the polarization plane is determined by orientation of the liquid crystal in the liquid crystal layer 124. Formation of an electrical field in the liquid crystal layer 124 by using a pixel electrode 150 and a common electrode 154 described later changes the initial orientation state of the liquid crystal to the oriented state determined by the electrical field. Transmittance of the liquid crystal element is changed according to the change of the orientation state, thereby realizing gray-scale display.

Referring to FIG. 4B, the connector 112 is connected to the terminals 208 (see FIG. 3) arranged at a vicinity of the short side of the display device 100. The IC chip 118 and the printed circuit substrate 116 may be further connected to the connector 112. As shown in FIG. 4B, the printed circuit substrate 116 may be arranged so as to overlap with the backlight 1190 by bending the connector 112. At this time, a part of or the whole of the connector 112 may overlap with the cover member 104. Bending the connector 112 in this way allows the display device 100 to be transformed into a compact shape. A resin film 132 for protecting the connector 112 may be disposed as an optional structure over the connector 112.

### 2. Display Unit

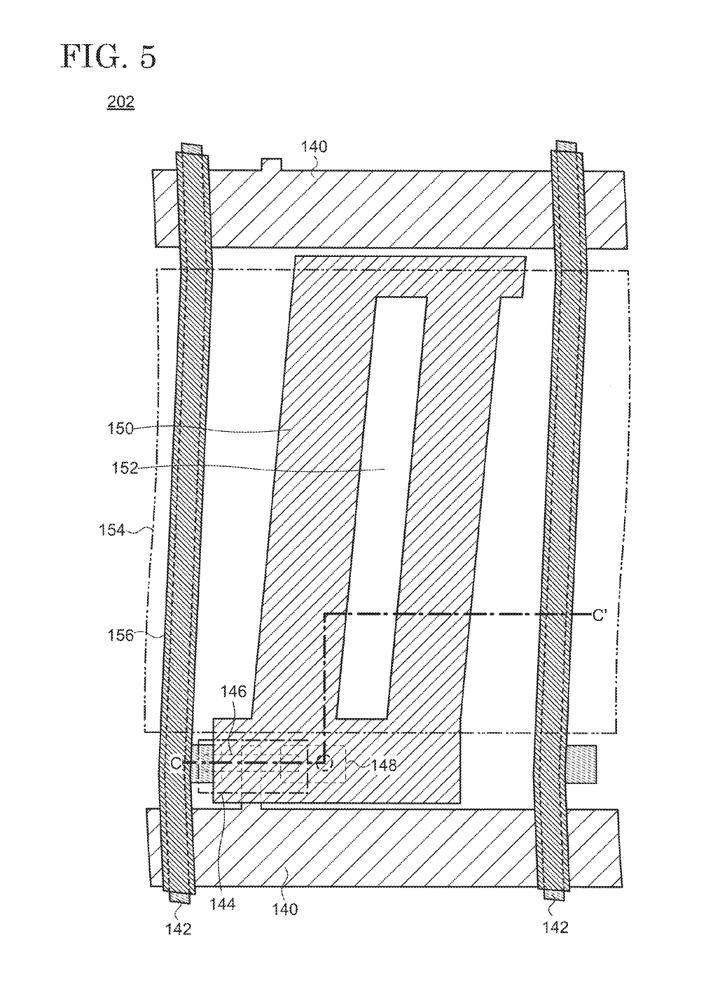

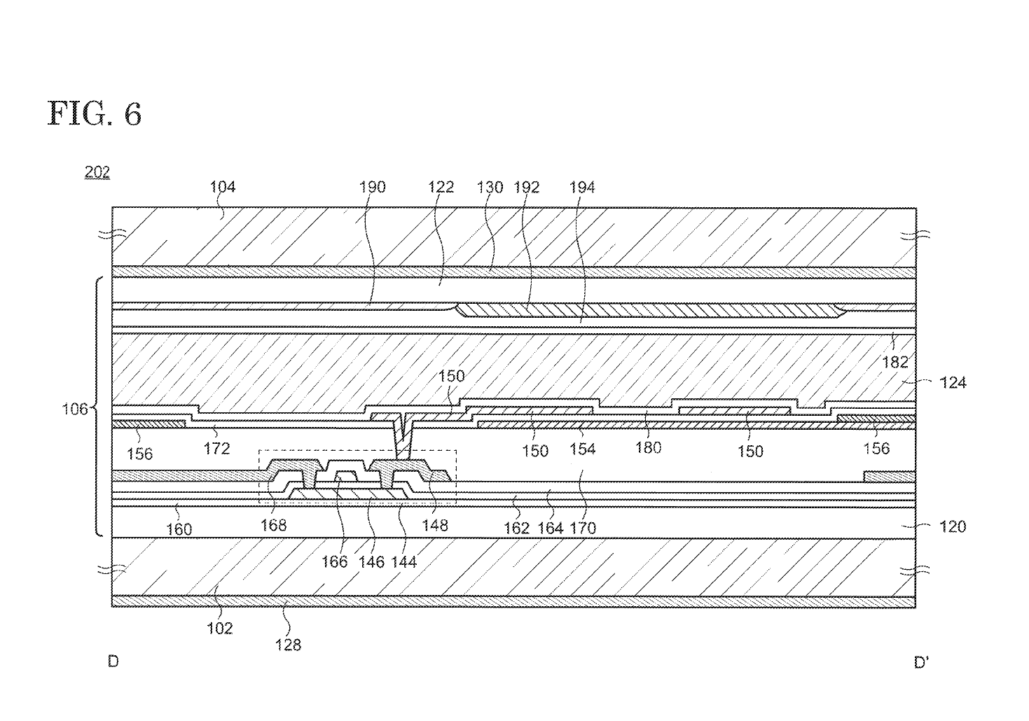

A structure of the display unit 106 is explained by using FIG. 5 and FIG. 6. FIG. 5 is a schematic top view of the pixel 202, and a schematic cross-sectional view along a chain line C-C′ of FIG. 5 corresponds to FIG. 6.

A plurality of gate signal lines (scanning lines) 140 and a plurality image signal lines 142 are provided in the display region 200. Each of the plurality of gate signal lines 140 controls the plurality of pixels 200 arranged in a direction in which the gate signal line 140 extends. Similarly, each of the plurality of image signal lines 142 is electrically connected to the plurality of pixels 202 arranged in a direction in which the image signal line 142 extends. A transistor 144 is disposed in each of the pixels 202. The transistor 144 includes a part of the gate signal line 140 (a portion protruding upward in the drawing), a semiconductor film (semiconductor layer) 146, a source electrode 148, and a part of the image signal line 142 (a portion protruding in a right direction in the drawing). The part of the gate signal line 140 functions as a gate electrode 166 of the transistor 144, and the part of the image signal line 142 functions as a drain electrode 168 of the transistor 144. Note that designation of the source electrode 148 and the drain electrode 168 may be interchanged with each other according to a current direction and a polarity of the transistor. Although not shown in the figure, the pixels 202 each may further contain a capacitor element and a semiconductor element such as a transistor other than the transistor 144.

The pixel 202 further possesses the common electrode 154 and the pixel electrode 150. The fundamental structure of the liquid crystal element is given by the common electrode 154, the pixel electrode 150, and the liquid crystal layer 124. The pixel electrode 150 may have a slit 152. Although the slit 152 shown in FIG. 5 has an opened shape, it may also have a closed shape. Alternatively, the pixel electrode 150 may have a slit with an opened shape in addition to the slit 152 with the closed shape. The pixel electrode 150 is electrically connected to the transistor 144. A signal corresponding to an image is supplied to the image signal line 142 and is applied to the pixel electrode 150 through the transistor 144.

The common electrode 154 is arranged in a stripe form in a direction in which the gate signal line 140 extends and shared by the plurality of pixels 202. The common electrode 154 is applied with a fixed potential during a period when an image is displayed and functions as one of the electrodes for applying a voltage to the liquid crystal layer 124. An example is shown in FIG. 5 in which the common electrode 154 is arranged in parallel to the gate signal line 140. However, the common electrode 154 may be arranged in parallel to the image signal line 142.

As an optional structure, the pixel 202 may have an auxiliary wiring 156 electrically connected to the common electrode 154. The auxiliary wiring 156 extends in a direction in which the image signal line 142 extends and may be shared by the plurality of pixels 202. When the common electrode 154 includes a conductive oxide transmitting visible light, such as indium-tin oxide (ITO) and indium-zinc oxide (IZO), a voltage drop readily occurs because these conductive oxides have relatively high resistance compared with a metal such as aluminum, copper, tungsten, titanium, and molybdenum. Moreover, the common electrode 154 may be divided into a plurality of portions to be utilized as a touch-sensing electrode. In this case, each portion has a small area, which readily leads to the voltage drop.

Hence, the voltage applied to the common electrode 154 may be significantly different between the pixels 202. However, the low conductivity of ITO, IZO, and the like can be supplemented by providing the auxiliary wiring 156 including a metal so as to be in contact with the common electrode 154, thereby preventing or suppressing the voltage drop. The auxiliary wiring 156 may be disposed over or under the common electrode 154.

As shown in FIG. 6, the display unit 106 includes a variety of patterned films. Specifically, the first base material 120 is formed so as to be in contact with the glass substrate 102, and the transistor 144 is disposed over the first base material 120 via an undercoat film 160 which is an optical structure. The transistor 144 includes the gate electrode 166, a gate insulating film 162, the semiconductor film 146, an interlayer film 164, the source electrode 148, and the drain electrode 168. The transistor 144 shown in FIG. 6 is a top-gate type transistor. However, the structure of the transistor 144 is not limited, and the transistor 144 may be a bottom-gate type transistor or have a structure in which gate electrodes are arranged over and under the semiconductor film 146. Moreover, there is no limitation to a vertical relationship between the semiconductor film 146 and the source electrode 148 and between the semiconductor film 146 and the drain electrode 168.

A leveling film 170 is formed over the transistor 144, by which depressions and projections caused by the transistor 144 and the like are absorbed, and a flat surface is provided to the leveling film 170. The common electrode 154 is disposed over the leveling film 170. When the auxiliary wiring 156 is arranged, the auxiliary wiring 156 is formed over or under the common electrode 154 so as to be in contact with the common electrode 154.

The display unit 106 further possesses an insulating film 172 covering the common electrode 154 and the leveling film 170. The insulating film 172 has a function to electrically insulate the common electrode 154 from the pixel electrode 150. The pixel electrode 150 is provided over the leveling film 170 and the insulating film 172 and is electrically connected to the source electrode 148 in an opening portion formed in the leveling film 170 and the insulating film 172. A first orientation film 180 is further disposed over the pixel electrode 150, and the liquid crystal layer 124 is formed thereover. Formation of a potential difference between the common electrode 154 and the pixel electrode 150 results in an electrical field substantially parallel to the top surface of the first base material 120 in the liquid crystal layer 124. The liquid crystal in the liquid crystal layer 124 is rotated by this electrical field, by which the polarization plane of the polarized light passing through the liquid crystal layer 124 is rotated. Thus, the display device 100 functions as a FFS (Fringe Field Switching) liquid crystal display device which is a kind of the so-called IPS (In-Plane Switching) liquid crystal display devices. Note that the display device 100 is not limited to an IPS liquid crystal display device and may be a TN (Twisted Nematic) liquid crystal display device or a VA (Vertical Alignment) liquid crystal display device.

The second base material 122 is disposed over the first orientation film 180 through the liquid crystal layer 124. The second base material 122 may be provided with a light-shielding film (black matrix) 190, a color filter 192, an overcoat 194 covering the light-shielding film 190 and the color filter 192, and the like.

The light-shielding film 190 has a function to block visible light and may be formed so as to overlap with the gate signal lines 140 and the image signal lines 142. The light-shielding film 190 may be arranged so as to overlap with the transistor 144. As can be appreciated from FIG. 5, when the light-shielding film 190 is provided so as to overlap with the gate signal lines 140 and the image signal lines 142, the light-shielding film 190 can be recognized as a single film having an opening. Thus, the opening of the light-shielding film 190 corresponds to a display region of each pixel 202.

The color filter 192 is provided in order to give colors to light extracted from each pixel 202 and overlaps with the opening of the light-shielding film 190. Therefore, the color filter 192 may be arranged so as to overlap with the pixel electrode 150 and the common electrode 154.

The second base material 122 further has a second orientation film 182 arranged so as to be in contact with the liquid crystal layer 124. Similar to the first orientation film 180, the second orientation film 182 has a function to orient the liquid crystal molecules. Although not shown in the figure, a spacer may be added to the liquid crystal layer 124 in order to maintain a constant gap between the glass substrate 102 and the second base material 122. Alternatively, a spacer may be formed on the second base material 122 so as to be positioned between the adjacent pixels 202.

The display device 100 further possesses the first polarizing plate 128 and the second polarizing plate 130 between the glass substrate 102 and the backlight 110 and between the second base material 122 and the cover member 104, respectively. The backlight 110 shown in FIG. 4A and the like is arranged under the first polarizing plate 128. The light emitted from the backlight 110 becomes polarized light when passing through the first polarizing plate 128. The polarization plane of this polarized light is rotated by the liquid crystal layer 124 when passing through the liquid crystal layer 124. Then, the light is partly absorbed with the color filter 192 to be colorized, passes through the second polarizing plate 130, and is extracted outside.

As described above, the pixels 202 may be formed in both of the flat region 120a and the bending regions 120b of the first base material 120. Furthermore, the liquid crystal layer 124 spreads between the flat region 120a and the flat region 122a and between the bending region 120b and the bending region 122b. That is, as indicated by the arrow in FIG. 4A, the display region 200 is formed across the flat portion and the bending portion. Hence, the display device 100 is capable of displaying an image not only on the top surface but also on the bent side surfaces. Additionally, a continuous image can be displayed across the top surface and the side surface.

In the flat portion, it is possible to provide a high-quality image without distortion due to the high flatness of the glass substrate 102. On the other hand, an image can be displayed on the side surfaces of the display device 100 by the pixels 202 located in the bending portion, allowing a user to obtain image information from the side surfaces of the display device 100 even in a state where the user does not face the display device 100. Moreover, when the display device 100 is viewed from a position facing the display device 100, both edge portions of the display region 200 are not shielded by a frame. Hence, a large display area is secured, and the display device 100 having high designability can be provided.

Although described in detail in the Second Embodiment, the display device 100 includes the glass substrate 102, which increases strength, facilitates handling the display device 100 in a manufacturing process, and allows the display device 100 capable of displaying a continuous image between the top and side surfaces to be manufactured at a good yield and low cost.

### Second Embodiment

In the present embodiment, an example of a manufacturing method of the display device 100 is explained. An explanation of the contents described in the First Embodiment may be omitted.

### 1. Display Unit

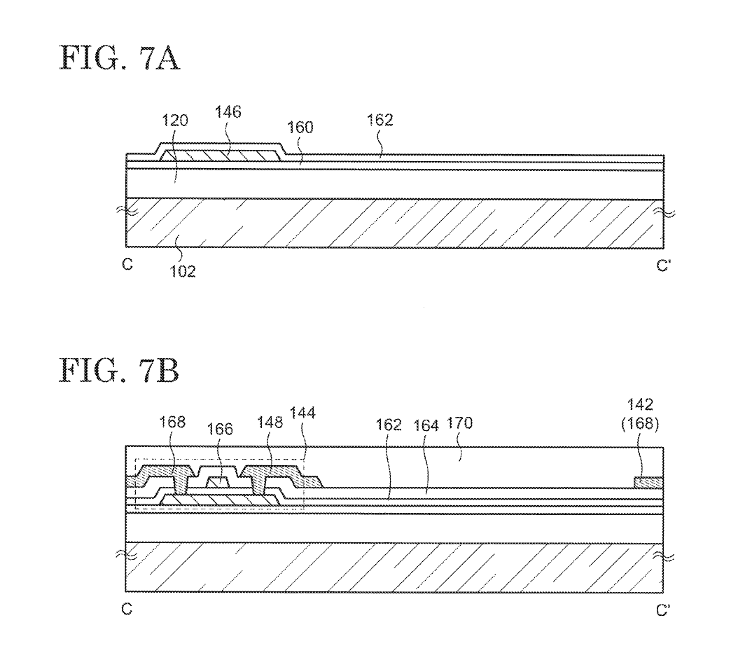

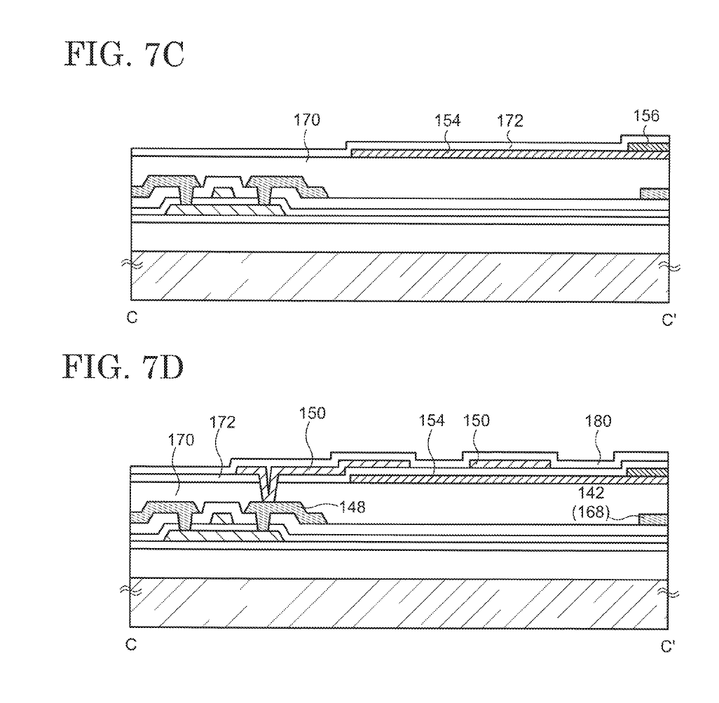

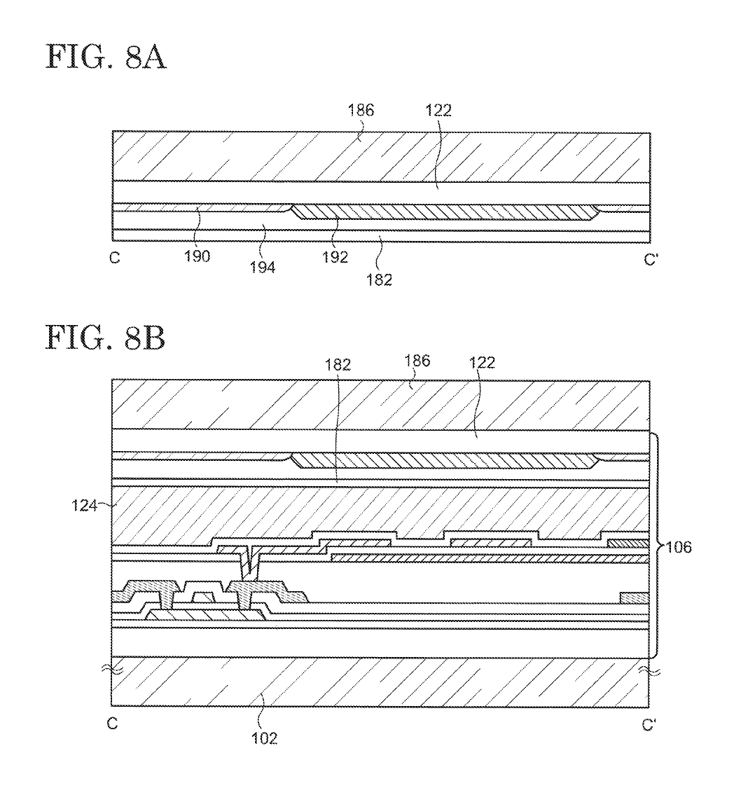

First, a manufacturing method of the display unit 106 is explained with reference to FIG. 7A to FIG. 8B. These drawings represent the cross section along the chain line C-C′ in FIG. 5 and correspond to FIG. 6.

As shown in FIG. 7A, the first base material 120 is formed over the glass substrate 102. The first base material 120 may have flexibility and include a polymer such as a polyimide, a polyamide, a polycarbonate, and a polyester. These polymers may include an aromatic ring in the main chain. The first base material 120 may be formed by applying a wet-type film-formation method such as a spin-coating method, a printing method, an ink-jet method, and a dip-coating method, a lamination method, or the like.

Next, the undercoat film 160 is formed over the first base material 120 (FIG. 7A). The undercoat film 160 has a function to prevent diffusion of impurities such as an alkaline metal ion from the glass substrate 102 and the first base material 120 to the transistor 144 and the liquid crystal layer 124. The undercoat film 160 may include an inorganic compound exemplified by a silicon-containing compound such as silicon nitride, silicon oxide, silicon nitride oxide, and silicon oxynitride.

Next, the semiconductor film 146 is prepared as shown in FIG. 7A. The semiconductor film 146 may include a Group 14 element such as silicon or an oxide semiconductor, for example. The semiconductor film 146 may include, as an oxide semiconductor, a Group 13 element such as indium and gallium, and a mixed oxide (IGO) of indium and gallium and a mixed oxide (IGZO) including indium, gallium, and zinc are represented as a typical example of an oxide semiconductor.

Furthermore, the display device 100 may be configured so that the transistor overlapping with the flat region 120a in which the glass substrate 102 exists has a Group 14 element in the semiconductor film, while the transistor formed in the bending regions 122b possesses an oxide semiconductor in the semiconductor film.

Next, the gate insulating film 162 is formed so as to cover the semiconductor film 146 (FIG. 7A). Then, the gate electrode 166 including a metal material is formed by using a sputtering method or a CVD method (FIG. 7B).

Next, the interlayer film 164 is formed so as to cover the gate electrode 166 and the semiconductor film 146 (FIG. 7B). After that, opening portions reaching the semiconductor film 146 are formed in the interlayer film 164 and the gate insulating film 162, which is followed by the formation of the image signal line 142, the drain electrode 168 which is a part of the image signal line 142, and the source electrode 148 so that they are electrically connected to the semiconductor film 146. The transistor 144 is formed up to this process. When the terminals 208 are not formed when the gate electrode 166 is formed, the terminals 208 can be formed when the image signal lines 142 are formed.

After that, the leveling film 170 is prepared so as to cover the transistor 144 (FIG. 7B). Then, the common electrode 154 is formed over the leveling film 170 (FIG. 7C). The common electrode 154 may include a conductive oxide transmitting visible light, such as ITO and IZO, for example. After that, the auxiliary wiring 156 is formed as an optional structure so as to overlap with the image signal line 142 and be in contact with the common electrode 154. The auxiliary wiring 156 may include a metal or an alloy usable in the gate electrode 166 and the image signal line 142. The auxiliary wiring 156 may be formed after forming the leveling film 170 and before forming the common electrode 154.

After that, the insulating film 172 is formed over the leveling film 170 to cover the common electrode 154 and the auxiliary wiring 156. Then, etching is performed on the insulating film 172 and the leveling film 170 to prepare an opening portion reaching the source electrode 148, and the pixel electrode 150 is prepared so as to cover the opening portion (FIG. 7D). With this process, the pixel electrode 150 and the source electrode 148 are connected to each other. The pixel electrode 150 may also include a conductive oxide transmitting visible light.

After that, the first orientation film 180 is formed (FIG. 7D). The first orientation film 180 may include a polymer such as a polyimide, a precursor thereof, a polyamide, and a polyester. An irradiation treatment with polarized light or a rubbing treatment is conducted on the first orientation film 180 in order to determine the orientation direction.

The second base material 122 is first disposed over a supporting substrate 186 (FIG. 8A). A substrate the same as or similar to the glass substrate 102 can be used as the supporting substrate 186. After that, the light-shielding film 190 is fabricated over the second base material 122 (FIG. 8A).

Next, the color filter 192 is formed in the opening portion of the light-shielding film 190 (FIG. 8A). The color filter 192 may be formed so as to cover a part of the light-shielding film 190. Alternatively, the light-shielding film 190 may be formed after forming the color filter 192.

After that, the overcoat 194 is formed so as to cover the light-shielding film 190 and the color filter 192 (FIG. 8A). Next, the second orientation film 182 is formed so as to cover the color filter 192 and the light-shielding film 190 (FIG. 8A). The second orientation film 182 may include a material the same as that of the first orientation film 180, and the same orientation treatment is performed thereon.

After that, the first base material 120 and the second base material 122 are bonded with a seal 126 so as to sandwich the first orientation film 180 and the second orientation film 182 (FIG. 8B, FIG. 4A). The seal 126 is arranged so as to surround the display region 200. The liquid crystal layer 124 is located between the first orientation film 180 and the second orientation film 182 (FIG. 8B).

### 2. Processing Display Unit

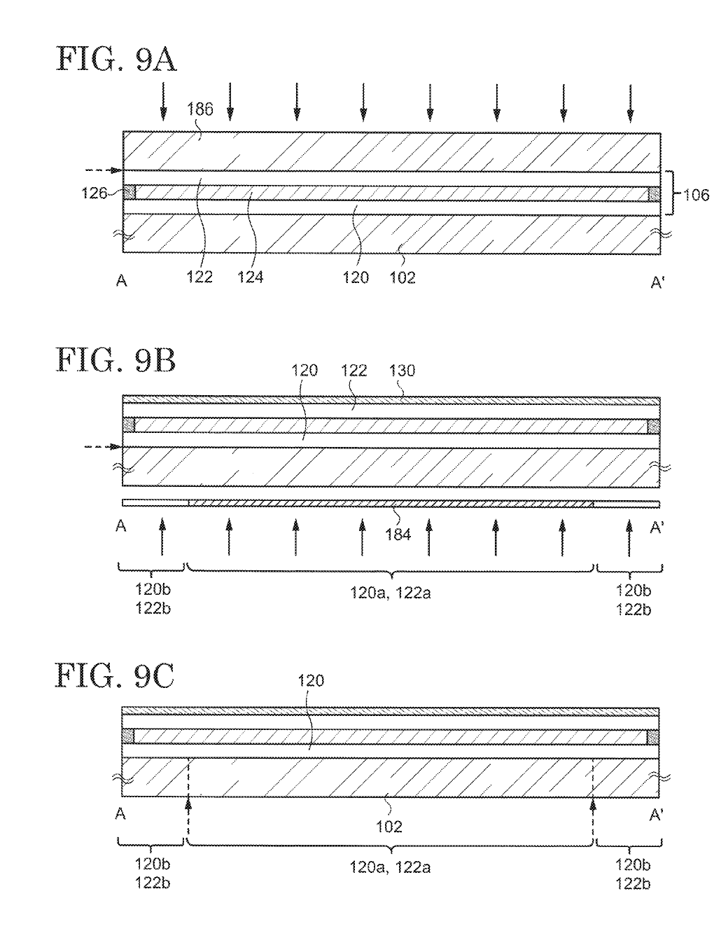

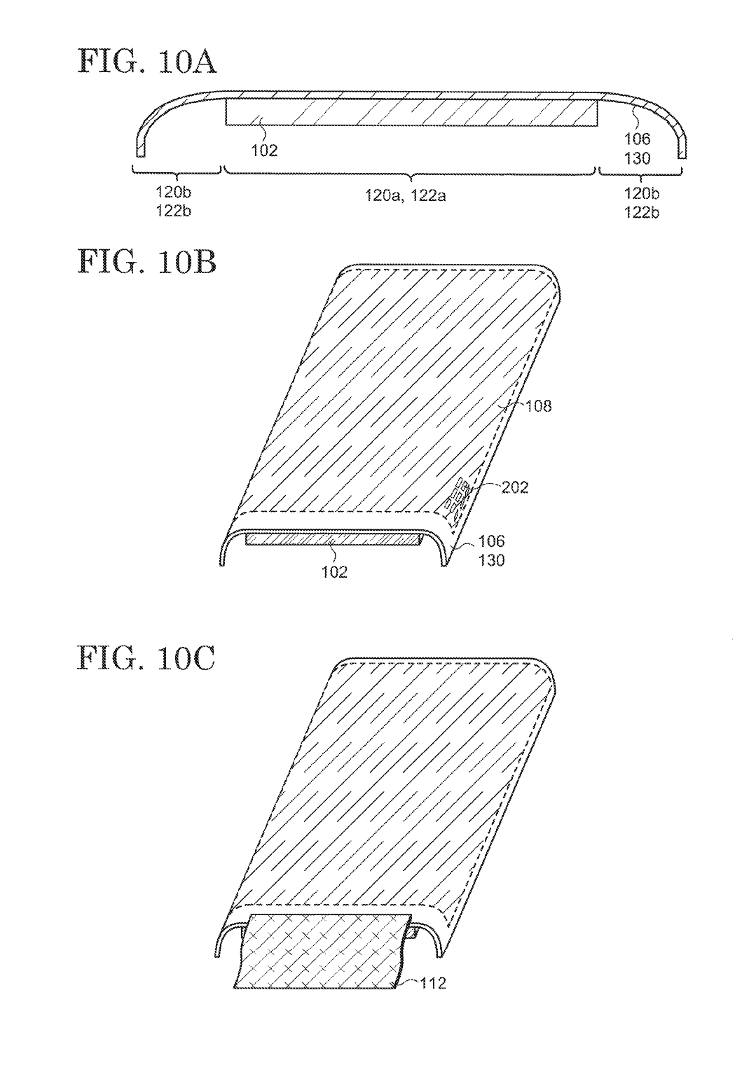

Next, the process of the display unit 106 is explained with reference to FIG. 9A to FIG. 11E. Other than FIG. 10B and FIG. 10C, these drawings correspond to the cross section along the chain line A-A′ of FIG. 1. In these drawings, a part of the variety of films structuring the display unit 106 is omitted.

As shown in FIG. 9A, the supporting substrate 186 is separated from the second base material 122. Specifically, light irradiation is performed on an interface (an interface indicated by a dotted arrow in the drawing) between the supporting substrate 186 and the second base material 122 by using a laser or a flash lamp to reduce adhesion between the supporting substrate 186 and the second substrate 122. After that, the supporting substrate 186 is physically separated along the interface. Peeling may be carried out by chemically removing the supporting substrate 186 with etching instead of the aforementioned light irradiation and the physical peeling.

The second polarizing plate 130 is formed over the second base material 122 after peeling the supporting substrate 186. After that, light-irradiation is conducted from a side of the glass substrate 102 to reduce adhesion of the interface (an interface indicated by a dotted arrow in the drawing) between the glass substrate 102 and the first base material 120 as shown in FIG. 9B. At this time, a photomask 184 may be used in order to avoid light irradiation on the portions where the flat regions 120a and 122a of the first base material 120 and the second base material 122 are to be formed, by which the portions where the bending regions 120b and 122b are to be formed are selectively irradiated with light. After that, the glass substrate 102 is scribed along the interface (an interface indicated by a dotted arrow in the drawing) between the region irradiated with light and the region which is not irradiated with light (FIG. 9C), and the glass substrate 102 located in the light-irradiated region is selectively peeled from the first base material 120. A laser (e.g., linear laser) may be selectively applied on a region where the peeling is performed instead of the use of a photomask 184 during the light irradiation.

A schematic cross-sectional view and perspective view at this state are shown in FIG. 10A and FIG. 10B, respectively. As can be appreciated from FIG. 9C, FIG. 10A, and FIG. 10B, the first base material 120 is in contact with the glass substrate 102 in the flat region 120a. On the other hand, the first base material 120 is spaced from the glass substrate 102 in the bending regions 120b.

After that, the connector 112 is connected to the terminals 208 formed in the flat region 120a (FIG. 10C). The connection is carried out with an anisotropic conductive film while applying pressure from over the display unit 106. The terminals 208 may also overlap with the glass substrate 102 via the flat region 120a of the first base material 120. Since the glass substrate 102 has sufficient rigidity, the movement of the first base material 120 in upward and downward directions can be suppressed when the connector 112 is connected. As a result, the connector 112 can be securely fixed, giving high reliability to the display device 100.

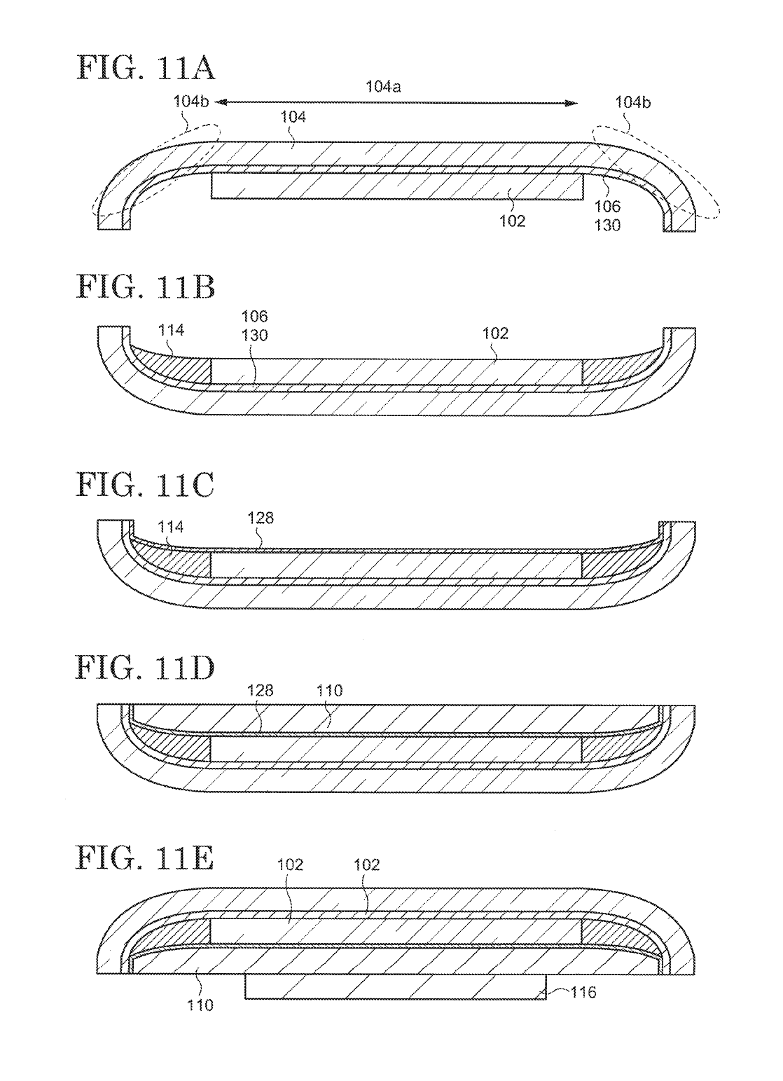

Next, the cover member 104 is bonded over the second polarizing plate 130 so that the display unit 106 is sandwiched by the cover member 104 and the glass substrate 102 (FIG. 11A). When bonding, an adhesive (not illustrated in the figure) may be used. As described above, the cover member 104 has the flat region 104a and the bending regions 104b, and the bonding is performed so that the flat region 104a overlaps with the glass substrate 102 and the flat regions 120a and 122a and the bending regions 104b overlap with the bending regions 120b and 122b. The bending regions 120b and 122b are arranged along surfaces of the bending regions 104b of the cover member 104 due to the flexibility of the first base material 120 and the second base material 122.

After that, the filler 114 is formed. Specifically, as shown in FIG. 11B, a polymer such as an acrylic resin, an epoxy resin, a polyimide, a polycarbonate, and a polyolefin is formed in the space surrounded by the side surface of the glass substrate 102 and the display unit 106. For example, a monomer or oligomers giving these resins or polymers is/are filled in this space and subjected to light-induced polymerization of thermal polymerization to cure the monomer or oligomers. Since the monomer and oligomers are fluid liquid, they are held in the space so as to have a gently declining top surface. Curing the monomer or oligomers in this state provides the surface of the filler 114 with a gently bent shape. That is, the distance between a plane formed by the surface of the glass substrate 102 and the surface of the filler 114 increases with increasing distance from the side surface of the glass substrate 102. Alternatively, the shape of the filler 114 may be controlled by pressing a template when curing is carried out. The template may be configured so that a three-dimensional shape thereof is the same as that of the backlight 110. The filler 114 is preferably formed so that no step is provided between the bottom surface of the glass substrate 102 (i.e., the surface of the glass substrate 102 which is not in contact with the display unit 106) and the surface of the filler 114.

After that, the first polarizing plate 128 is fabricated over the filler 114 and the glass substrate 102 (FIG. 11C), and the backlight 110 is arranged thereover (FIG. 11D). As shown in FIG. 11C, the first polarizing plate 128 may be disposed so as to be in contact with or not to be in contact with the display unit 106. As described above, the top surface of the backlight 110 (the surface closer to the first polarizing plate 128 in FIG. 11D) is able to possess a bending shape so that the thickness thereof decreases approaching the edge portion. Therefore, it is possible to arrange the backlight 110 so that its bending shape matches the surface of the filler 114. Although not shown in the figure, a retardation film and the like may be disposed over or under the first polarizing plate 128 before arranging the backlight 110.

After that, the printed circuit substrate 116 is connected to the connector 112, and the connector 112 is folded so that the printed circuit substrate 116 faces the display unit 106 with the glass substrate 102 sandwiched therebetween as shown in FIG. 1 and FIG. 4B (see also FIG. 11E). The display device 100 shown in FIG. 1 is obtained with this process.

As described above, the manufacturing method described in this embodiment enables production of the display device 100 having bent edge portions and capable of displaying an image continuous from the top surface to the side surface. Such a display device is usually manufactured by preparing a wholly flexible display unit and then arranging the display unit over the backlight 110. However, if flexibility is provided to the whole of a display unit, the display unit has poor strength and is difficult to be treated during a manufacturing process, which makes it difficult to be applied to mass-production.

In contrast, according to the manufacturing method described in this embodiment, the glass substrate 102 supporting the first base material 120 is not completely separated from the first base material 120 during the manufacturing process. Therefore, the display unit 106 does not entirely possess flexibility during the manufacturing process, and only the edge portions thereof exhibit flexibility. Hence, the display unit 106 can be readily treated because the display unit 106 maintains rigidity to some extent in order to maintain its shape. Due to these reasons, the display device 100 is suitable for a process for mass-production. Accordingly, application of the display device 100 and its manufacturing method according to the embodiments of the present invention enables production of a display device which is bent in an edge portion and has high rigidity and which is capable of displaying an image continuous from a top surface to a side surface at a good yield and low cost.

### Third Embodiment

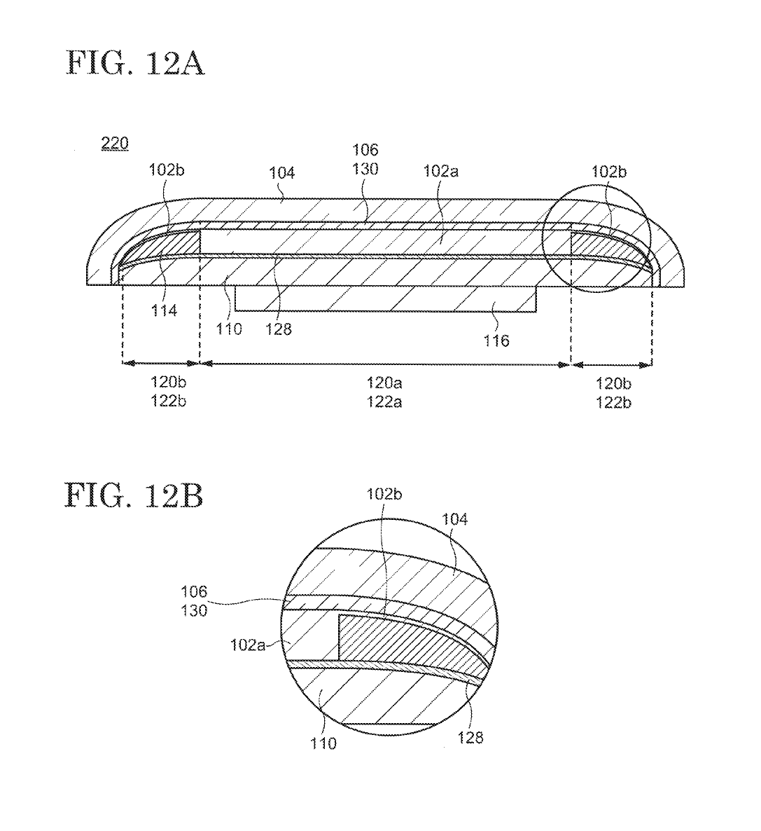

In the present embodiment, a display device 220 having a structure different from that of the display device 100 is explained with reference to FIG. 12A and FIG. 12B. FIG. 12B is an enlarged drawing of a portion surrounded by a circle in FIG. 12A. The display device 200 is different from the display device 100 in that a part of the glass substrate 102 extends to a region where the bending regions 120b and 122b of the first base material 120 and the second base material 122 overlap with each other. An explanation of the contents described in the First and Second Embodiments may be omitted.

Specifically, the glass substrate 102 possesses a flat region 102a and bending regions 102b as shown in FIG. 12A. The flat region 102a overlaps with the flat regions 120a and 122a of the first base material 120 and the second base material 122, and the bending regions 102b overlap with the bending regions 120b and 122b. Moreover, an angle of the normal line of the top surface of the glass substrate 102 with respect to the top surface of the glass substrate 102 in the flat region 102a continuously changes from the flat region 102a to the bending region 102b. A thickness of the bending region 102b is smaller than that of the flat region 102a and can be equal to or larger than 0.05 mm and equal to or smaller than 0.4 mm or equal to or larger than 0.1 mm and equal to or smaller than 0.3 mm. The glass substrate 102 may be configured so that the thickness of the bending region 102b decreases with increasing distance from the flat region 102a. The filler 114 may be in contact with a side surface of the flat region 102a and a bottom surface of the bending region 102b. A structure is shown in FIG. 12A where the bending regions 102b are provided at both edge portions of the glass substrate 102 and the flat region 102a is sandwiched by the bending regions 102b. However, the bending region 102b may be formed only at one of the edge portions of the glass substrate 102.

Formation of the bending regions 102b thinner than the flat region 102a prevents the bottom surface of the first base material 120 of the display unit 106 from being exposed to impurities and the like during the manufacturing process. Therefore, it is possible to remarkably reduce the probability of the display unit 106 becoming contaminated. Additionally, formation of the bending regions 102b provides higher rigidity to the display unit 106, which further facilitates treatment during manufacture and enables production of the display device 200 at a good yield and low cost.

### Fourth Embodiment

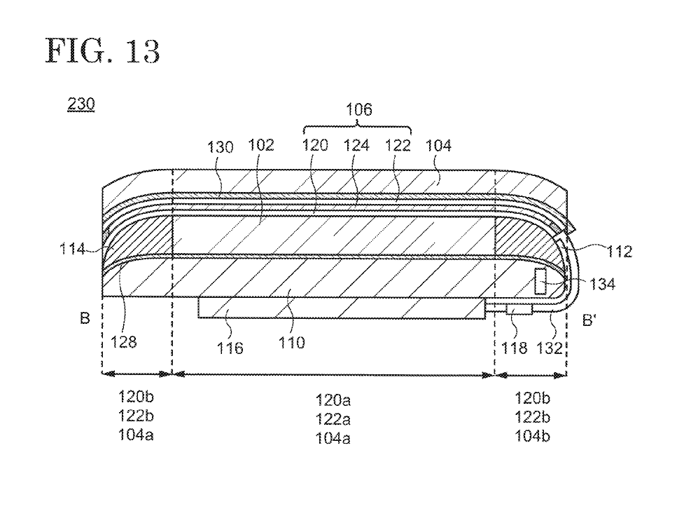

In the present embodiment, a display device 230 having a structure different from those of the display devices 100 and 200 is explained with reference to FIG. 13. The display device 230 is different from the display devices 100 and 200 in that bending regions 120b, 122b, and 104b of the first base material 120, the second base material 122, and the cover member 104 are provided at the edge portions on the short sides of the display device 100. An explanation of the contents described in the First to Third Embodiments may be omitted.

A cross section corresponding to the chain line B-B′ in FIG. 1 is schematically illustrated in FIG. 13. As shown in FIG. 13, the display device 230 has bending portions on the short side to which the connector 112 is connected and on another short side facing this short side. Similar to the display devices 100 and 220, the first base material 120, the second base material 122, and the cover member 104 each may have two bending regions 120b, 122b, and 104b, respectively, or one of the respective bending regions 120b, 122b, and 104b. A light source 134 disposed in the backlight 110 may be provided so as to overlap with the bending regions 120b, 122b, and 104b close to the connector 112 as shown in FIG. 13. Alternatively, the light source 134 may be arranged so as to overlap with the bending regions 120b, 122b, and 104b facing the former bending regions.

When such display device 230 is viewed from a facing position, both edges on the short sides of the display region 200 are not shielded by the frame. Therefore, a wide area can be secured for the display region 200, and a display device with high designability can be provided. Furthermore, it is not necessary for the connector 112 to cover the top surface of the glass substrate 102 as shown in FIG. 13. Hence, it is possible to reduce an area where the connector is bent, thereby decreasing strain applied to wirings in the connector 112. As a result, disconnection of the wirings can be suppressed, and reliability of the display device can be increased.

### Fifth Embodiment

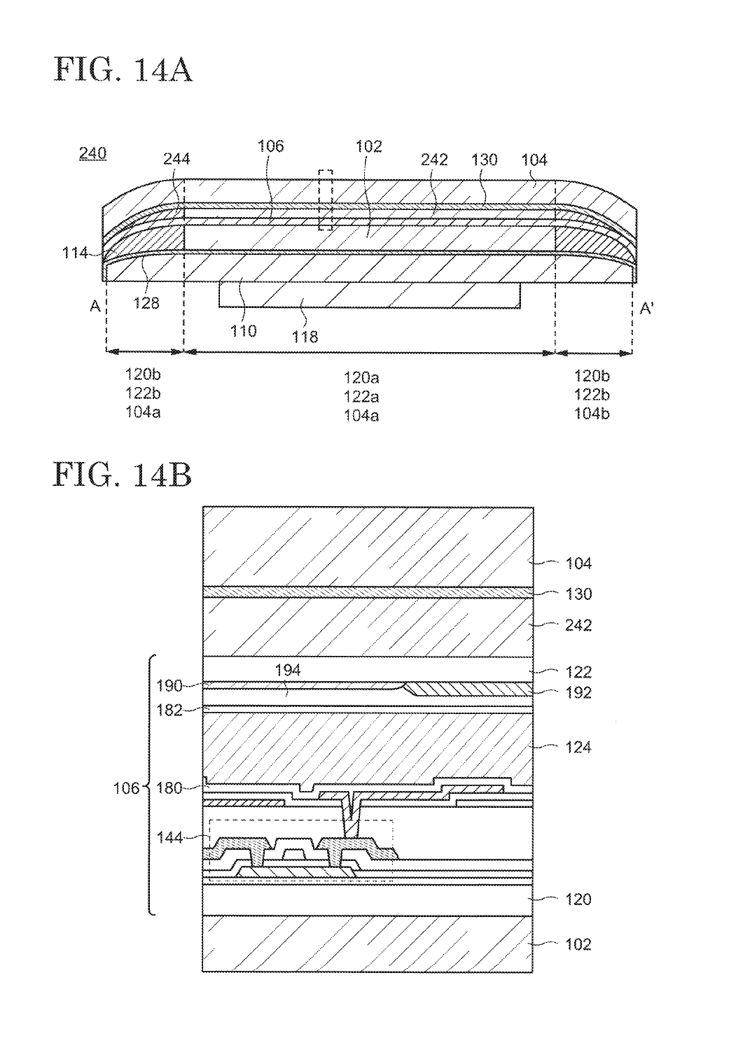

In the present embodiment, a display device 240 with a structure different from those of the display devices 100, 200, 220, and 230 is explained with reference to FIG. 14A and FIG. 14B. FIG. 14A schematically shows the cross section corresponding to the chain line A-A′ in FIG. 1, and FIG. 14B is an enlarged drawing of a region surrounded by a dotted rectangle in FIG. 14A. The display device 240 is different from the display devices 100, 200, 220, and 230 in that the display device 240 possesses a second glass substrate 242 and a second filler 244 between the display unit 106 and the second polarizing plate 130 and that the second polarizing plate 130 is disposed between the second glass substrate 242 and the cover member 104. An explanation of the contents described in the First to Fourth Embodiments may be omitted.

Specifically, the display device 240 has the second glass substrate 242 over the display unit 106 as shown in FIG. 14A. The second glass substrate 242 is a flat or a substantially flat substrate and overlaps with the glass substrate 102. A plane shape and area of the second glass substrate 242 may be the same as those of the glass substrate 102. A thickness of the second glass substrate 242 may be the same as or different from that of the glass substrate 102. In FIG. 14A, the second glass substrate 242 is etched so as to be thinner than the glass substrate 102. As shown in FIG. 14B, the second glass substrate 242 may be provided so as to be in contact with the second base material 122. The bending regions 122b of the second base material 122 are spaced from the second glass substrate 242.

The second filler 244 is formed so as to overlap with the filler 114 with the display unit 106 sandwiched therebetween. The second filler 244 is provided so as to fill a space surrounded by a side surface of the second glass substrate 242, the bending region 120b of the second base material 122, and the second polarizing plate 130 and overlaps with the bending regions 120b and 122b. A lower surface of the second filler 244 may be in contact with the second base material 122 and can be bent along a top surface of the bending region 122b of the second base material 122.

The second polarizing plate 130 may be disposed over the second glass substrate 242 and the second filler 244. In this case, the second polarizing plate 130 is sandwiched between the cover member 104 and the second glass substrate 242 and between the cover member 104 and the second filler 244.

Although detail is omitted, when the display device 240 having the structure described above is manufactured, the second polarizing plate 130 is disposed in the depressed surface of the cover member 104, and the second glass substrate 242 is bonded thereover. Then, the second filler 244 is formed in the space provided by the side surface of the second glass substrate 242 and the second polarizing plate 130. After that, this structural body is bonded to the glass substrate 102 so as to sandwich the display unit 106, which is followed by the formation of the filler 114. Hence, unlike the manufacturing method explained in the Second Embodiment, the second polarizing plate 130 is not directly formed over the second base material 122 with flexibility and the liquid crystal layer 124 arranged thereunder, but is formed over the cover member 140 having sufficient rigidity. Therefore, it is possible to securely and precisely fix the second polarizing plate 130 to the cover member 104, which increases the yield of the display device.

Note that, when the second glass substrate 242 is prepared, the process shown in FIG. 9C to remove only the bending regions 120b from the glass substrate 102 may be applied to the supporting substrate 186. In other words, the second glass substrate 242 shown in FIG. 14A may be prepared by applying the peeling treatment from the second base material 122 and the scribing treatment of the edge portions to the supporting substrate 186. In this case, the manufacturing process is simplified, and a manufacturing throughput is increased.

### Sixth Embodiment

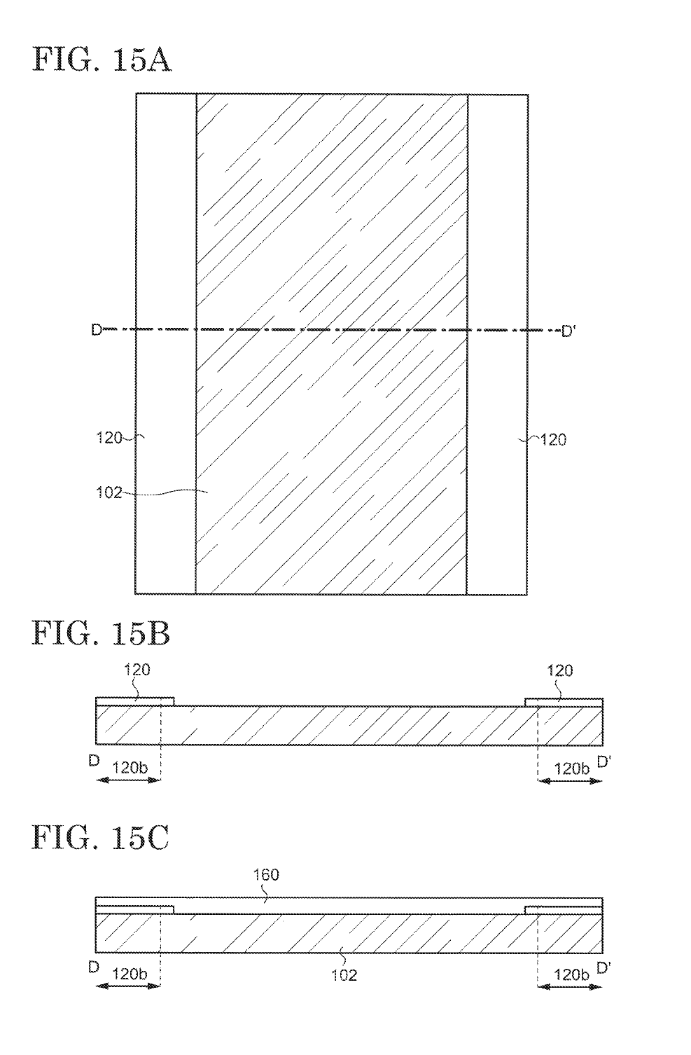

In the present embodiment, a manufacturing method different from that of the display device 100 described in the Second Embodiment is explained with reference to FIG. 15A to FIG. 15C. FIG. 15B and FIG. 15C are schematic cross-sectional views along a chain line D-D′ in FIG. 15A. An explanation of the contents described in the First to Fifth Embodiments may be omitted.

The manufacturing method described in the present embodiment is different from that of the Second Embodiment in that the first base material 120 is partly formed over the glass substrate 102. Specifically, the first base material 120 is selectively formed over the portions of the glass substrate 102 overlapping with the regions where the bending regions 120b and 122b are to be fabricated as shown in FIG. 14A and FIG. 14B. The formation of the first base material 120 can be conducted by the aforementioned wet-type film-formation method or a lamination method. In the case where a wet-type film-formation method is utilized, the amount of material required to form the first base material 120 can be reduced by using an ink-jet method. As a result, the display device can be manufactured at low cost.

When the first base material 120 is partly formed, steps are caused due to the thickness thereof (FIG. 15B). These steps can be canceled by increasing a thickness of the undercoat film 160 (FIG. 15C). Alternatively, a stacked structure including a film containing a polymer such as an epoxy resin and an acrylic resin and a film containing a silicon-containing compound may be employed for the undercoat film 160. The steps can be effectively canceled because the former film is prepared by a wet-type film-formation method.

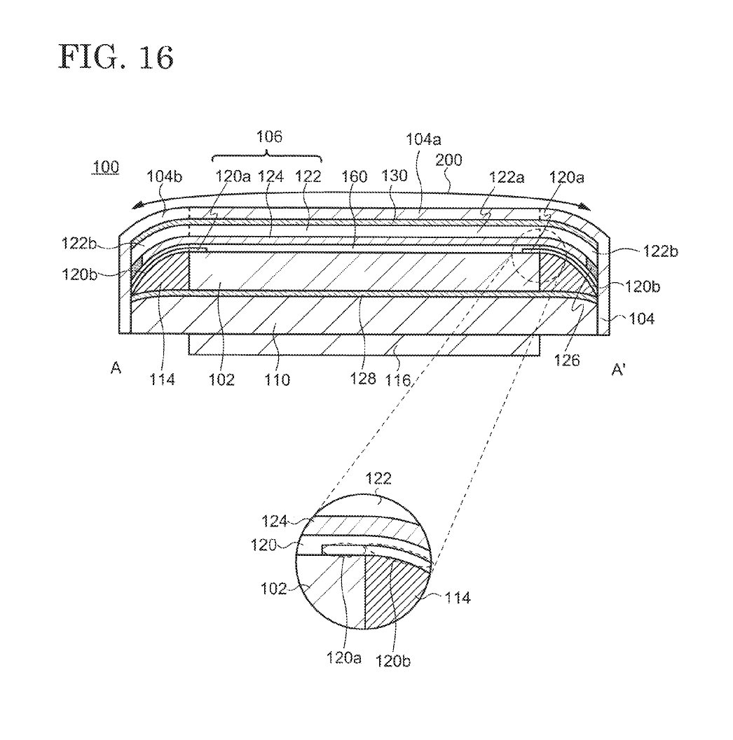

Similar to the process of the Second Embodiment, the insulating films and the semiconductor films are prepared in the following process. After the formation of the insulating films and the semiconductor films, the portions corresponding to the bending regions 120b of the glass substrate 102 are removed, thereby giving the flat region 120a and the bending regions 120b to the first base material 120 as shown in FIG. 16. Note that, similar to FIG. 4A, the variety of films provided between the undercoat film 160 and the liquid crystal layer 124 are not illustrated in FIG. 16.

When the first substrate 120 is partly disposed, the display device 100 may be configured so that the semiconductor film of the transistor (second transistor) 144_2 located over the bending regions 120b and the semiconductor film of the transistor (first transistor) 144_1 located in the region where the first base material 120 is not provided may be different from each other in material included therein. In this case, there is no problem if a high-temperature manufacturing process is applied to the first transistor 144_1 because the flexible first base material 120 is not included in the flat region 102a. Hence, the semiconductor film of the first transistor 144_1 may include polysilicon, and the semiconductor film of the second transistor 144_2 can include an oxide semiconductor.

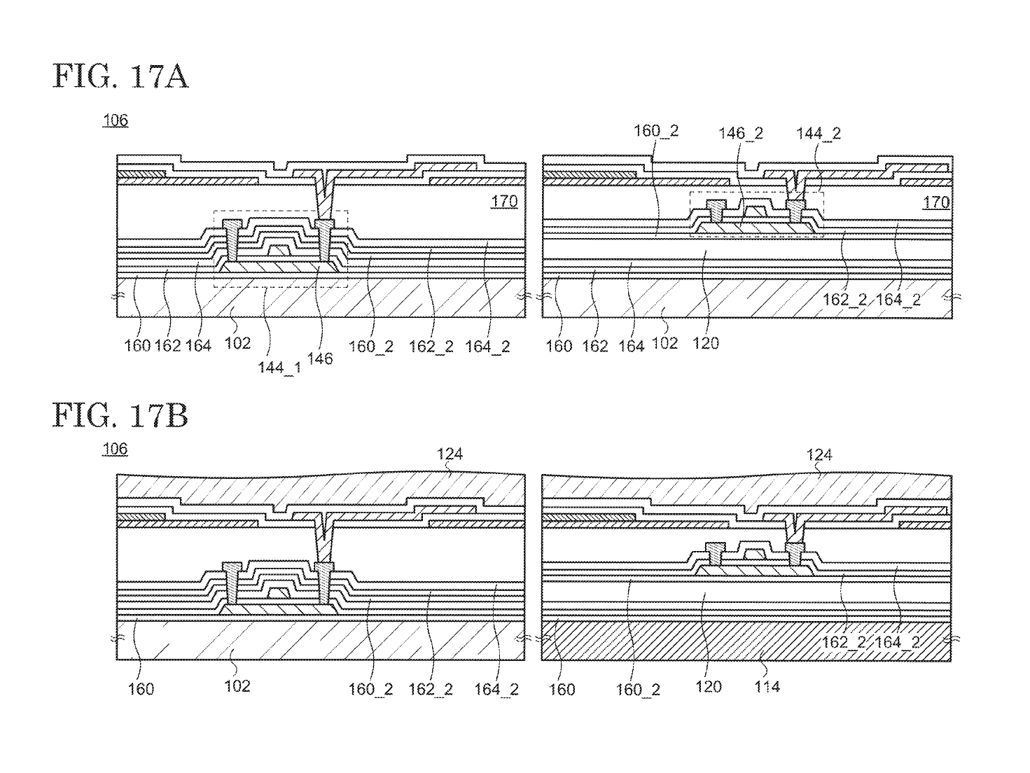

In such an embodiment, as shown in the cross-sectional views of the first transistor 144_1 and the second transistor 144_2 (FIG. 17A), the undercoat film 160 is first formed over the glass substrate 102, and then the first transistor 144_1 is fabricated thereover according to the manufacturing method described in the Second Embodiment. In this case, the undercoat film 160, the gate insulating film 162, and the interlayer film 164 also may be formed over the entire surface of the glass substrate 102.

After that, the first base material 120 is selectively formed, and then a second undercoat film 160_2 and the second transistor 144_2 are formed. A semiconductor film 146_2 can be prepared with a sputtering method using an oxide semiconductor as a target. The second undercoat film 160_2 as well as a second gate insulating film 162_2 and a second interlayer film 164_2, which structure the second transistor 144_2, may be formed over the first transistor 144_1. The following process is the same as that described in the Second Embodiment. The glass substrate 102 is peeled in the region where the second transistor 144_2 is formed, and the filler 114 is provided under the undercoat film 160 (FIG. 17B). With this process, the flat region 120a and the bending regions 122b are formed in the second base material 120.

When a polyimide or a polyamide is used for the first base material 120, transmittance with respect to visible light tends to decrease with increasing thermal resistivity of the first base material 120. Therefore, the first base material 120 with high transmittance is formed in the bending regions 120b while the first base material 120 is not formed in the flat region 120a, and the transistor utilizing polysilicon with high electrical conductivity is fabricated in the flat region 120a with high thermal resistivity, thereby increasing quality of an image displayed on the flat region 120a.

### Seventh Embodiment

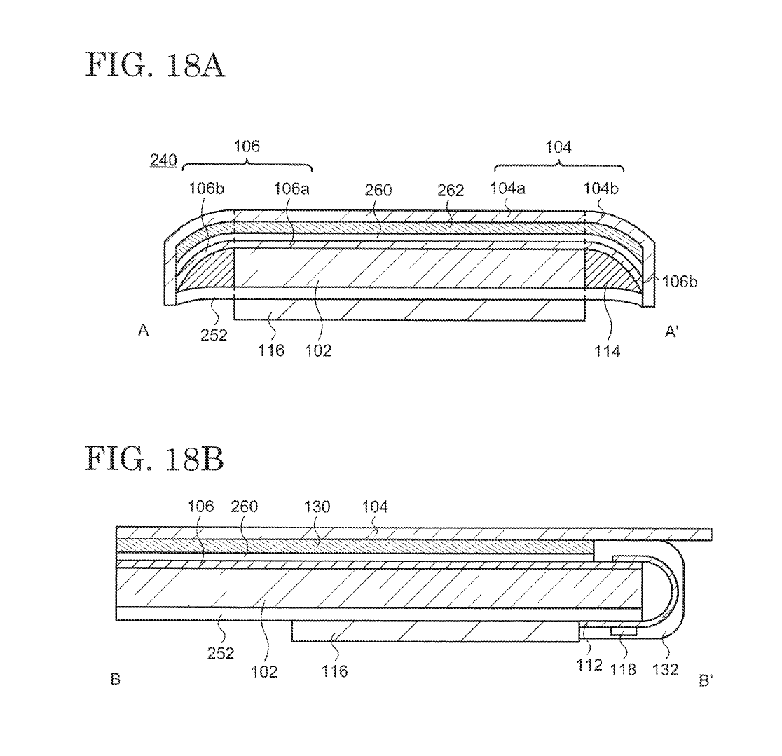

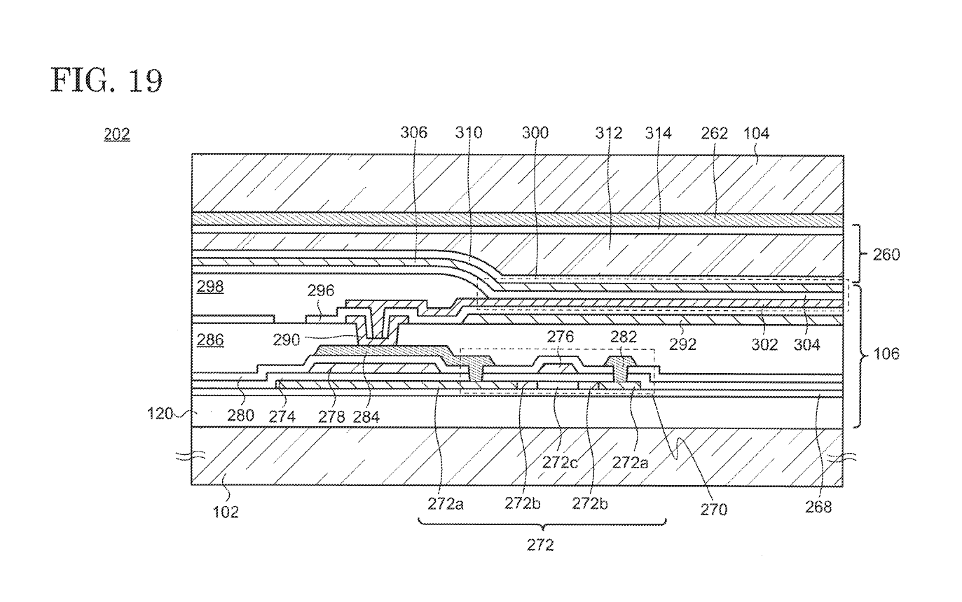

In the present embodiment, a display device 250 to which the display unit 106 including a light-emitting element as an electro-optical element is provided is explained with reference to FIG. 18A, FIG. 18B, and FIG. 19. FIG. 18A and FIG. 18B are schematic views of the cross sections corresponding to the chain lines A-A′ and B-B′ in FIG. 1, respectively, and FIG. 19 is a schematic cross-sectional view of the pixel 202. An explanation of the contents described in the First to Sixth Embodiments may be omitted.

As shown in FIG. 18A and FIG. 18B, the display device 240 has a glass substrate 102, the display unit 106 formed thereover, and a sealing film (passivation film) 260 over the display unit 106. The display device 240 further possesses the cover member 104 over the sealing film 260. As an optional structure, a polarization plate 262 may be disposed between the sealing film 260 and the cover member 104.

Similar to the display device 100, the display unit 106 may be configured so that the edge portions are bent. For example, both edge portions on the long sides or the short sides of the display unit 106 are bent so as to cover the side surfaces of the glass substrate 102. More specifically, the display unit 106 has the flat region 106a overlapping with the glass substrate 102 and the bending regions 106b which do not overlap with and are spaced from the glass substrate 102. Similar to the cover member 104 of the display device 100, the cover member 104 has the flat region 104a and the bending regions 104b which overlap with the flat region 106a and the bending regions 106b, respectively. The cover member 104 may be in contact with the side surface of the display unit 106. The side surfaces of the polarizing plate 262 and the sealing film 260 may also be in contact with the cover member 104.

A supporting film 252 may be disposed as an optional structure under the glass substrate 102. In this case, the printed circuit substrate 116 may be arranged under the glass substrate 102 with the supporting film 250 sandwiched therebetween. A side surface of the supporting film 252 also may be in contact with the cover member 104. The supporting film 252 may include a polymer such as an aromatic polycarbonate, a polyester such as poly(ethylene terephthalate), or a polyolefin.

As shown in FIG. 19, the display unit 106 is structured by the first base material 120 as well as the stack of a variety of films formed over the first base material 120. For example, the display unit 106 possesses, in the pixel 202, an undercoat film 268 over the first base material 120, a semiconductor film 272, a gate insulating film 274, a gate electrode 276, a capacitor electrode 278, an interlayer film 280, a drain electrode 282, a source electrode 284, a leveling film 286, a connection electrode 290, a supplementary capacitor electrode 292, an insulating film 296, a first electrode 302, a partition wall 298, an electroluminescence layer (EL layer) 304, a second electrode 306, and the like. The semiconductor film 272 may have a channel region 272c overlapping with the gate electrode 276, doped regions 272a doped with impurities, and low-concentration doped regions 272b located between the channel region 272c and the doped regions 272a and having an impurity concentration lower than that of the doped regions 272b. A transistor 270 is structured by the semiconductor film 272, the gate insulating film 274, the gate electrode 276, the interlayer film 280, the drain electrode 282, and the source electrode 284.

The light-emitting element 300 is structured by the first electrode 302, the electroluminescence layer 304, and the second electrode 306. In the present specification and claims, the electroluminescence layer 304 means all of the layers sandwiched by the first electrode 302 and the second electrode 306 and may be configured with a plurality of layers (e.g., a carrier-injection layer, a carrier-transporting layer, an emission layer, a carrier-blocking layer, and the like). The first electrode 302 and the source electrode 284 are electrically connected via the connection electrode 290, by which the light-emitting element 300 is controlled by the transistor 270. In the present specification and claims, when a light-emitting element is included as an electro-optical element, the display unit 106 means the first base material 120, the light-emitting element 300, and a variety of films sandwiched therebetween.

The sealing film 260 may have a film including an insulator such as a silicon-containing inorganic compound. In the example shown in FIG. 19, the sealing film 260 possesses a first layer 310 and a third layer 314 including a silicon-containing inorganic compound as well as a second layer 312 sandwiched therebetween and including an organic compound. The display device 240 may be configured so that the sealing film 260 is in contact with the second electrode 306 and the polarizing plate 262.

In such a display device 240, high image quality is obtained even in the bending portion because the all-solid type light-emitting element 300 is disposed in each pixel 202. Hence, it is possible to provide a high-quality image from the side surface of the display device 240.

In the specification, although the cases of the display devices having a liquid crystal element or a light-emitting element are exemplified, the embodiments can be applied to any kind of display devices of the flat panel type such as an electronic paper type display device having electrophoretic elements and the like. In addition, it is apparent that the size of the display device is not limited, and the embodiment can be applied to display devices having any size from medium to large.

It is properly understood that another effect different from that provided by the modes of the aforementioned embodiments is achieved by the present invention if the effect is obvious from the description in the specification or readily conceived by persons ordinarily skilled in the art.

What is claimed is:

1. A display device comprising:
a first glass substrate;
a first base material over the first glass substrate, the first base material having a first flat region and a first bending region; and
an electro-optical element over the first flat region,
wherein the first base material is in contact with the first glass substrate in the first flat region and is spaced from the first glass substrate in the first bending region.

2. The display device according to claim 1,
wherein the first base material is not in contact with the first glass substrate in the first bending region.

3. The display device according to claim 1, further comprising a filler,
wherein the filler is in contact with a side surface of the first glass substrate and is in contact with a bottom surface of the first base material in the first bending region.

4. The display device according to claim 1, further comprising a second base material including a second flat region overlapping with the first flat region and a second bending region overlapping with the first bending region.

5. The display device according to claim 4, further comprising a cover member over the second base material,
wherein the cover member comprises:
a third flat region overlapping with the first flat region; and
a third bending region overlapping with the first bending region.

6. The display device according to claim 5, further comprising a polarizing plate between the second base material and the cover member.

7. The display device according to claim 1,
wherein the first base material has a plurality of first bending regions, and
the first flat region is located between the plurality of first bending regions.

8. The display device according to claim 1, further comprising a first transistor and a second transistor over the first base material,
wherein the first transistor and the second transistor are located in the first flat region and the first bending region, respectively,
the first transistor includes a polysilicon layer as a semiconductor, and
the second transistor includes an oxide semiconductor layer as a semiconductor.

9. The display device according to claim 2, further comprising a filler,
wherein the filler is in contact with a side surface of the first glass substrate and is in contact with a bottom surface of the first base material in the first bending region.

10. The display device according to claim 2, further comprising a second base material including a second flat region overlapping with the first flat region and a second bending region overlapping with the first bending region.

11. The display device according to claim 3, further comprising a second base material including a second flat region overlapping with the first flat region and a second bending region overlapping with the first bending region.

12. The display device according to claim 2,
wherein the first base material has a plurality of first bending regions, and
the first flat region is located between the plurality of first bending regions.

13. The display device according to claim 3,
wherein the first base material has a plurality of first bending regions, and
the first flat region is located between the plurality of first bending regions.

14. The display device according to claim 4,
wherein the first base material has a plurality of first bending regions, and
the first flat region is located between the plurality of first bending regions.

15. A display device comprising:
a first glass substrate;
a first base material over the first glass substrate, the first base material having a first flat region and a first bending region;
an electro-optical element over the first flat region and the first bending region;
a second base material over the electro-optical element, the second base material having a second flat region and a second bending region; and
a second glass substrate over the second base material,
wherein the first base material is in contact with the first glass substrate in the first flat region and is spaced from the first glass substrate in the first bending region, and
the second base material is in contact with the second glass substrate in the second flat region.

16. The display device according to claim 15, further comprising a cover member over the second base material,
wherein the cover member comprises:
a third flat region overlapping with the first flat region; and
a third bending region overlapping with the first bending region and the second bending region.

17. The display device according to claim 15, further comprising a first filler,
wherein the first filler is in contact with a side surface of the first glass substrate and is in contact with a bottom surface of the first base material in the first bending region.

18. The display device according to claim 16, further comprising a second filler,
wherein the second filler is located between the second bending region and the third bending region.

19. The display device according to claim 16, further comprising a polarizing plate between the second glass substrate and the cover member.

20. The display device according to claim 16, further comprising a first filler,
wherein the first filler is in contact with a side surface of the first glass substrate and is in contact with a bottom surface of the first base material in the first bending region.
